(19) United States
(12) Patent Application Publication
(10) Pub. No.: US 2006/0221010 A1
(43) Pub. Date: Oct. 5, 2006

(54) Display, array substrate, and method of driving display

(76) Inventor: Kazuyoshi Omata, Fukaya-shi (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/386,743

(22) Filed: Mar. 23, 2006

(30) Foreign Application Priority Data
Mar. 31, 2005 (JP) 2005-105100

(51) Int. Cl. G09G 3/30

(52) U.S. Cl. 345/76

(57) ABSTRACT

Each pixel of a display includes a drive circuit including a drive transistor whose source is connected to a first power supply terminal, a switch group switching between a state that drain and gate of the drive transistor and a video signal line are connected to one another and a state that they are disconnected from one another, and a capacitor connected between a first constant potential terminal and the gate, a reset circuit including a reset transistor and a reset switch connected in series between a second constant potential terminal and the video signal line, a drain of the reset transistor being directly connected or connected via the reset switch to a gate of the reset transistor, a display element, and an output control switch connected in series with the display element between the drain of the drive transistor and a second power supply terminal.

### CROSS-REFERENCE TO RELATED APPLICATIONS

This application is based upon and claims the benefit of priority from prior Japanese Patent Application No. 2005-105100, filed Mar. 31, 2005, the entire contents of which are incorporated herein by reference.

### BACKGROUND OF THE INVENTION

1. Field of the Invention

The present invention relates to a display, an array substrate and a method of driving a display.

2. Description of the Related Art

In a display such as organic electroluminescent (EL) display which controls the optical characteristics of each display element by a magnitude of a drive current passed through the display element, image quality deterioration such as luminance unevenness occurs if magnitudes of the drive currents vary. Therefore, when an active matrix driving method is used in this display, the pixels must be the same in characteristics of a drive transistor for controlling the magnitude of the drive current. In this display, however, the drive transistors are normally formed on an insulator such as a glass substrate, so the characteristics of them easily vary.

U.S. Pat. No. 6,373,454 describes an organic EL display using a current mirror circuit in a pixel.

This pixel includes an n-channel field-effect transistor as the drive transistor, an organic EL element, and a capacitor.

The source of the drive transistor is connected to a power supply line at a low electric potential, and the capacitor is connected between the gate of the drive transistor and the power supply line. The anode of the organic EL element is connected to a power supply line at a higher electric potential.

The pixel circuit is driven as-described below.

First, the drain of the n-channel field-effect transistor is connected to its gate. A current I_{sig} at a magnitude corresponding to a video signal is made to flow between the drain and source of the n-channel field-effect transistor. This operation sets the voltage between electrodes of the capacitor, equal to a gate-to-source voltage necessary for the n-channel field-effect transistor to pass the current I_{sig} through its channel.

Then, the drain of the n-channel field-effect transistor is disconnected from its gate, and the voltage between the electrodes of the capacitor is maintained. The drain of the n-channel field-effect transistor is subsequently connected to the cathode of the organic EL element. This allows a drive current I_{drv} at a magnitude almost equal to that of the current I_{sig} to flow through the organic EL element. The organic EL element emits light at a luminance corresponding to the magnitude of the drive current I_{drv}.

The above configuration makes it possible for the drive current I_{drv}, which flows between the drain and source of the n-channel field-effect transistor during a retention period following a write period, to have a magnitude almost equal to a magnitude of the current I_{sig} supplied as a video signal during the write period. Therefore, the influence of not only the threshold value Vₜₕ but also the mobility, dimensions, and the like of the n-channel field-effect transistor on the drive current I_{drv} can be eliminated.

However, each gray level within a low gray level range is prone to be displayed higher than that to be displayed, and therefore, it is difficult to realize the contrast ratio as designed.

### BRIEF SUMMARY OF THE INVENTION

According to a first aspect of the present invention, there is provided a display comprising pixels and video signal lines arranged correspondently with columns which the pixels form, each of the pixels comprising a drive circuit including a drive transistor whose source is connected to a first power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor, a reset circuit including a reset transistor and a reset switch connected in series between a second constant potential terminal and the video signal line, a drain of the reset transistor being directly connected to a gate of the reset transistor or connected to the gate of the reset transistor via the reset switch, a display element including a pixel electrode, a counter electrode connected to a second power supply terminal, and an active layer interposed between the pixel electrode and the counter electrode, and an output control switch connected between the drain of the drive transistor and the pixel electrode.

According to a second aspect of the present invention, there is provided an array substrate comprising pixel circuits and video signal lines arranged correspondently with columns which the pixel circuits form, each of the pixel circuits comprising a drive circuit including a drive transistor whose source is connected to a power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor; a reset circuit including a reset transistor and a reset switch connected in series between a second constant potential terminal and the video signal line, a drain of the reset transistor being directly connected to a gate of the reset transistor or connected to the gate of the reset transistor via the reset switch, a pixel electrode, and an output control switch connected between the drain of the drive transistor and the pixel electrode.

According to a third aspect of the present invention, there is provided a method of driving a display comprising pixels, video signal lines arranged correspondently with columns which the pixels form, and a video signal line driver to which the video signal lines are connected, each of the pixels comprising a drive circuit including a drive transistor whose source is connected to a first power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor, a reset circuit including a reset transistor and a reset switch connected in series between a second constant potential terminal and the video signal line, a drain of the reset transistor being directly connected to a gate of the reset transistor or connected to the gate of the reset transistor via the reset switch, a display element including a pixel electrode, a counter electrode connected to a second power supply terminal, and an active layer interposed between the pixel electrode and the counter electrode, and an output control switch connected between the drain of the drive transistor and the pixel electrode, comprising sequentially selecting rows which the pixels form, executing a write operation on each of the pixels included in the selected row, the write operation including switching the connection state from the second state to the first state, making the video signal line driver output a video signal to the pixel via the video signal line, and switching the connection state from the first state to the second state while keeping the reset switch and the output control switch opened, and executing a reset operation every time before executing the write operation, the reset operation including disconnecting the video signal lines from the video signal line driver and closing the reset switch in each of the pixels while keeping the second state in each of the pixels.

### BRIEF DESCRIPTION OF THE SEVERAL VIEWS OF THE DRAWING

FIG. 1 is a plan view schematically showing a display according to an embodiment of the present invention;

FIG. 2 is a sectional view schematically showing an example of a structure that can be used in the display shown in FIG. 1;

FIG. 3 is an equivalent circuit diagram showing a pixel included in the display shown in FIG. 1; and

FIG. 4 is a timing chart schematically showing an example of a method of driving the display shown in FIG. 1.

### DETAILED DESCRIPTION OF THE INVENTION

Embodiments of the present invention will be described below in detail with reference to the drawings. In the drawings, components having similar functions are denoted by the same reference numerals and duplicate descriptions will be omitted.

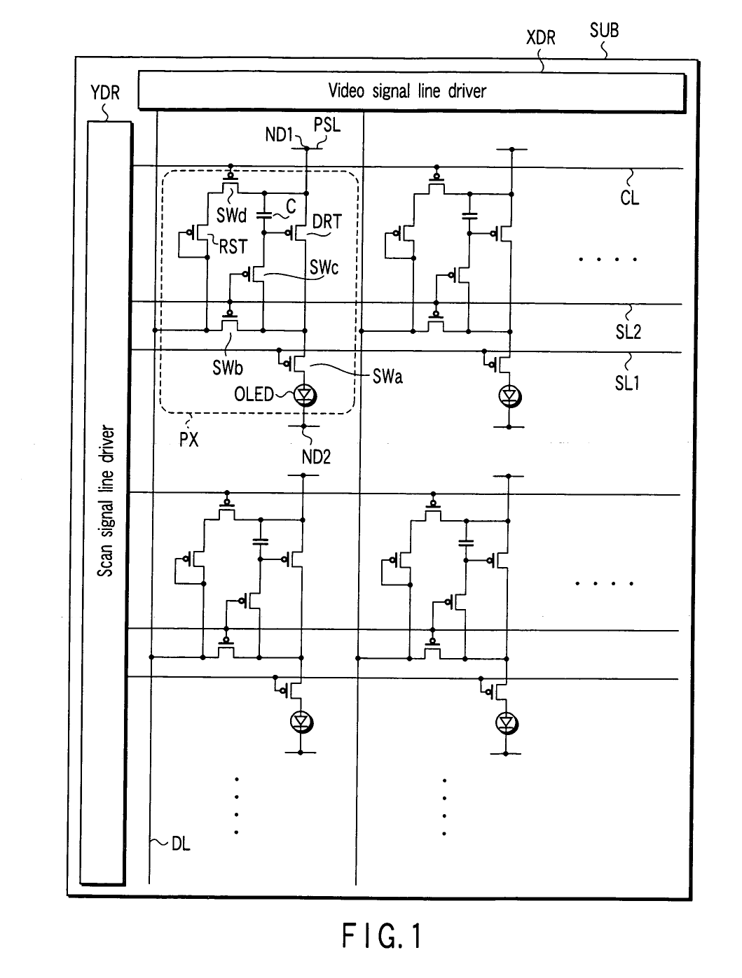

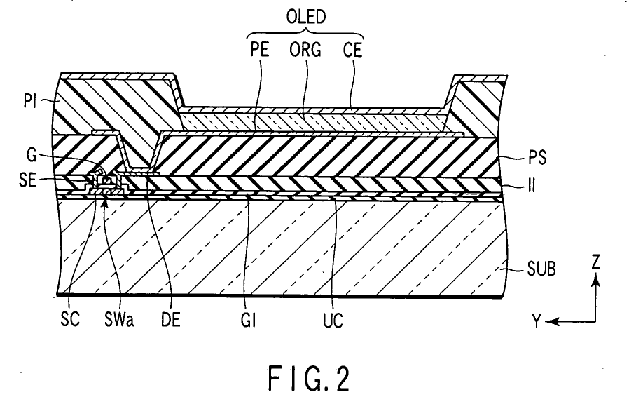

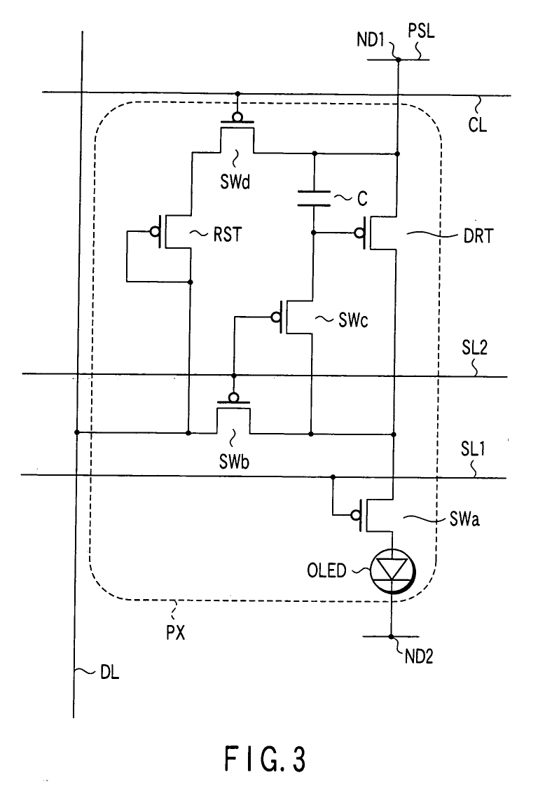

FIG. 1 is a plan view schematically showing a display according to an embodiment of the present invention. FIG. 2 is a sectional view schematically showing an example of a structure that can be used in the display shown in FIG. 1. FIG. 3 is an equivalent circuit diagram showing a pixel included in the display shown in FIG. 1. In FIG. 2, the display is drawn so that its display surface, that is, its front surface or light emitting surface faces the bottom of the drawing, while its back surface faces the top of the drawing.

This display is a bottom emission organic EL display which employs an active matrix driving method. The organic EL display includes an insulating substrate SUB such as glass substrate.

For example, an SiNₓ layer and an SiOₓ layer are sequentially stacked on the substrate SUB as an undercoat layer UC shown in FIG. 2.

Semiconductor layers SC such as polysilicon layers are arranged on the undercoat layer UC. Source and drain are formed in each polysilicon layer SC.

The undercoat layer UC and semiconductor layers SC are covered with a gate insulator GI. The gate insulator GI can be made from tetraethyl orthosilicate (TEOS), for example.

Gates G are arranged on the gate insulator GI. Gates G are made of MoW, for example.

The semiconductor layers SC, gate insulator GI, and gates G form top-gate type thin-film transistors. In the present embodiment, the thin-film transistors are utilized as drive transistors DRT, reset transistors RST, and switches SWa to SWd included in pixels PX shown in FIGS. 1 and 3.

On the gate insulator GI, bottom electrodes of capacitors C, scan signal lines SL1 and SL2, and control lines CL shown in FIGS. 1 and 3 are further arranged. These components can be formed in the same process as that for forming the gates G.

As shown in FIG. 1, the scan signal lines SL1 and SL2 extend along the rows of the pixels PX, i.e., in an X direction, and are arranged in a Y direction along the columns of the pixels PX. The scan signal lines SL1 and SL2 are connected to a scan signal line driver YDR.

The control lines CL extend the X direction and are arranged in the Y direction, for example. The control lines CL are connected to the scan signal line driver YDR.

An interlayer insulating film II shown in FIG. 2 covers the gate insulator GI, gates G, scan signal lines SL1 and SL2, control lines CL, and top electrodes of the capacitors C. The interlayer insulating film II is, for example, an SiOₓ film formed by plasma CVD. Parts of the interlayer insulating film II are utilized as dielectric layers of the capacitors C.

On the interlayer insulating film II, top electrodes of the capacitors C shown in FIGS. 1 and 3, source electrodes SE and drain electrodes DE shown in FIG. 2, and video signal lines DL and power supply lines PSL shown in FIGS. 1 and 3 are arranged. The top electrodes of the capacitors C, source electrodes SE, drain electrodes DE, video signal lines DL, and power supply lines PSL can be formed in the same process and may have a three-layer structure of, for example, Mo, Al, and Mo.

The source electrodes SE and drain electrodes DE are electrically connected to the sources and drains of the thin-film transistors via contact holes formed in the interlayer insulting film II.

As shown in FIG. 1, the video signal lines DL extend in the Y direction and are arranged in the X direction. The video signal lines DL are connected to a video signal line driver XDR.

The power supply lines PSL extend in the Y direction and are arranged in the X direction, for example.

A passivation film PS shown in FIG. 2 covers the source electrodes SE, drain electrodes DE, video signal lines DL, power supply lines PSL, and top electrodes of the capacitors C. The passivation film PS is made of, for example, SiNₓ.

As shown in FIG. 2, first electrodes PE as pixel electrodes are arranged on the passivation film PS. In the present embodiment, the first electrodes PE are light-transmissive front electrodes. Each first electrode PE is connected through a through-hole formed in the passivation film PS to the drain electrode DE to which the drain of the switch SWa is connected.

In this embodiment, the first electrodes PE are anodes. A transparent conductive oxide, for example, indium tin oxide (ITO) can be used as a material of the first electrodes PE.

A partition insulating layer PI shown in FIG. 2 is further placed on the passivation film PS. The partition insulating layer PI has through-holes formed at positions corresponding to the first electrodes PE or slits formed at positions corresponding to columns or rows formed by the first electrodes PE. Here, by way of example, the partition insulating layer PI has through-holes formed at positions corresponding to the first electrodes PE.

The partition insulating layer PI is, for example, an organic insulating layer. The partition insulating layer PI can be formed using, for example, a photolithography technique.

An organic layer ORG as an active layer including an emitting layer is placed on each of the first electrodes PE. The emitting layer is, for example, a thin film containing a luminescent organic compound that emits red, green, or blue light. In addition to the emitting layer, the organic layer ORG may include a hole injection layer, a hole transporting layer, a hole blocking layer, an electron transporting layer, and an electron injection layer.

The partition insulating layer PI and the organic layer ORG are covered with a second electrode CE as a counter electrode. The second electrode CE is a common electrode shared among the pixels PX. In this embodiment, the second electrode CE is a light-reflective cathode serving as a back electrode. For example, an electrode wire (not shown) is formed on the layer on which the video signal lines DL are formed, and the second electrode CE is electrically connected to the electrode wire via a contact hole formed in the passivation film PS and partition insulating layer PI. Each organic EL element OLED includes the first electrode PE, organic layer ORG, and second electrode CE.

Each pixel PX includes a drive circuit, reset circuit, organic EL element OLED, and output control switch SWa. The drive circuit includes the drive transistor DRT, selector switch SWb, diode-connecting switch SWc, and capacitor C. The reset circuit includes the reset transistor RST and reset switch SWd. As described above, the drive transistor DRT, reset transistor RST, and switches SWa to SWd are p-channel thin-film transistors. The switches SWb and SWc form a switch group which switches between a first state that the drain and gate of the drive transistor and the video signal line DL are connected together, and a second state that they are disconnected from one another.

The drive transistor DRT, output control switch SWa, and organic EL element OLED are connected in series between a first power supply terminal ND1 and second power supply terminal ND2 in this order. In this embodiment, the first power supply terminal ND1 is a high-potential power supply terminal, and the second power supply terminal ND2 is a low-potential power supply terminal.

The gate of the output control switch SWa is connected to the scan signal line SL1. The selector switch SWb is connected between the video signal line DL ad the drain of the drive transistor DRT. The gate of the switch SWb is connected to the scan signal line SL2. The diode-connecting switch SWc is connected between the drain and gate of the drive transistor DRT. The gate of the switch SWc is connected to the scan signal line SL2.

The capacitor C is connected between a first constant-potential terminal and the gate of the drive transistor DRT. In this embodiment, the first constant-potential terminal is connected to the first power supply terminal ND1.

The reset switch SWd and reset transistor RST are connected in series between a second constant-potential terminal and the video signal line DL in this order. In the present embodiment, the second constant-potential terminal is connected to the first power supply terminal ND1.

The gate of the reset switch SWd is connected to the control line CL. The gate of the reset transistor RST is connected to the drain of the reset transistor RST.

Note that an array substrate corresponds to a structure of the organic EL display from which the video signal line driver XDR, scan signal line driver YDR, organic layer ORG and second electrode CE are omitted, or a structure of the organic EL display from which the video signal line driver XDR, scan signal line driver YDR, partition insulating layer PI, organic layer ORG and second electrode CE are omitted. The array substrate may include the video signal line driver XDR and/or the scan signal line driver YDR.

The organic EL display is driven by, for the example, the method described below.

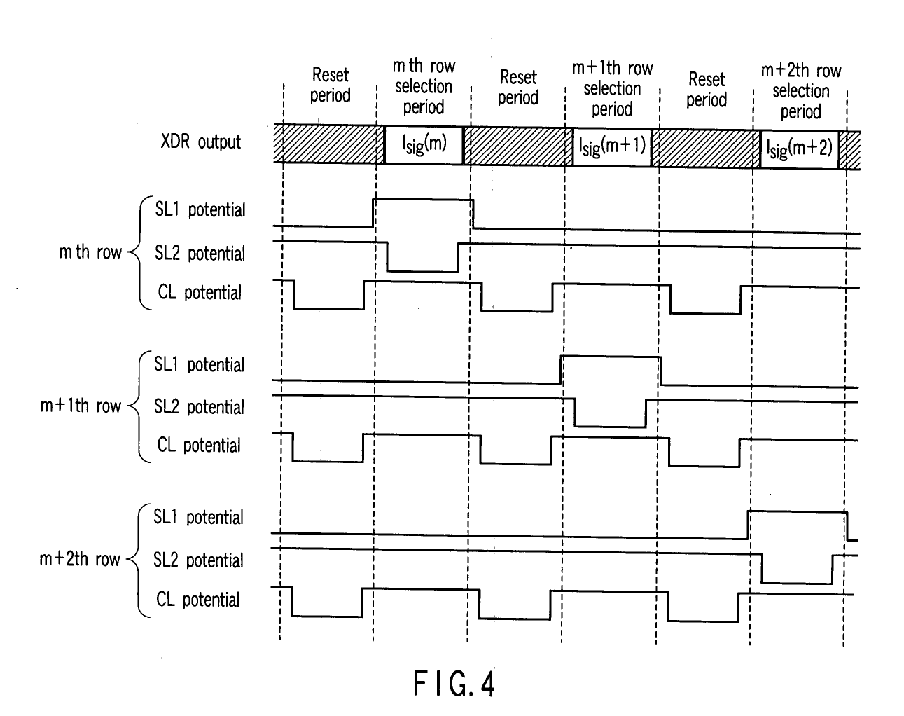

FIG. 4 is a timing chart schematically showing an example of a method of driving the display shown in FIG. 1.

In FIG. 4, the abscissa indicates time, while the ordinate indicates potential. As for the “XDR output” in FIG. 4, during the period shown as “I_{sig}(m+M)”, the video signal line driver XDR outputs a video signal I_{sig}(m+M) to the video signal line DL. During the periods shown as the hatched areas, the video signal line DL is disconnected from the video signal line driver XDR, for example. In FIG. 4, the waveforms shown as “SL1 potential” and “SL2 potential” represent the potentials of the scan signal lines SL1 and SL2, respectively, and the waveform shown as “CL potential” represents the potential of the control line CL.

According to the method shown in FIG. 4, the rows of the pixels PX are selected sequentially. A write operation is executed on each pixel PX in the selected row, and an emission operation is executed on each pixel PX in the non-selected rows. Further, a reset period is provided between a selection period over which a row is selected and a selection period over which the next row is selected, and a reset operation is executed during the reset operation. That is, in the driving method, the reset period and selection period are repeated alternately.

During the reset period, all the video signal lines DL are disconnected from the video signal line driver XDR to set the video signal lines DL into an electrically floating state. Then, the switches SWd are closed (conduction state) to connect the video signal lines DL in the floating state to the first power supply terminal ND1, while the switches SWb and SWc are kept open (non-conduction state). Typically, the switches SWa are kept closed. After a certain time period has elapsed, the switches SWd are opened to terminate the reset period.

Let V_{dd} be the potential of the first power supply terminal ND1. Let also Vₜₕ2(Av) be the mean value of the threshold voltages of the reset transistors RST for all the pixels PX connected to a certain video signal line DL. The potential of the above video signal line DL at the time just finished the reset operation can be expressed by the sum V_{dd}+Vₜₕ2(AV). That is, by executing the reset operation, the potential of each video signal line DL can be set at a reset potential Vᵣₛₜ =V_{dd}+Vₜₕ2(AV).

When a gray level is to be displayed on the pixels PX in the m-th row, the switches SWa in the pixels PX are opened during the period over which the pixels PX in the m-th row are selected (m-th row selection period). During the period over which the switches SWa are kept open, the following write operation is executed on each pixel PX in the m-th row. That is, the video signal lines are connected to the video signal line driver XDR. Then, the switches SWb and SWc are closed, while the switches SWa and SWd are kept closed. In this state, the video signal line driver XDR outputs video signals to the video signal lines DL. In other words, The video signal line driver XDR allows write currents I_{sig}(m) to flow from the first power supply terminal ND1 to the video signal lines DL. After a certain time period has elapsed, the switches SWb and SWc are opened. The write operation set the gate-to-source voltage of the drive transistor DRT to a value at which the drive transistor allows the write current I_{sig}(m) to flow. Note that the period over which the switches SWb and SWc are closed is the write period, and the period over which the switches SWb and SWc are opened is the retention period.

The m-th row selection period is terminated by closing the switches SWa of the pixels PX in the m-th row. When the switches SWa are closed, a drive current I_{drv}(m) flows through each organic EL element OLED at a magnitude corresponding to a magnitude of the write current I_{sig}(m). The organic EL element OLED emits light at a luminance corresponding to a magnitude of the drive current I_{drv}(m). This emission operation continues until the next m-th row selection period starts.

During the reset period following the m-th row selection period, the above reset operation is executed. During the m+1-th row following the reset period, the same write operation is executed on each pixel PX in the m+1-th row as that executed on each pixel PX in the m-th row. After that, the reset period and selection period are repeated alternately as the reset period, m+2-th row selection period, reset period, m+3-th row selection period, . . . .

For example, when a gray level within a high gray level range is displayed on the pixels in the m-th row, the potentials of the video signal lines DL at the time just starting the m+1-th row selection period are set at a potential much lower than the sum V_{dd}+Vₜₕ1, which correspond to the lowest gray level, of the potential V_{dd} of the first power supply terminal ND1 and the threshold voltage Vₜₕ1 of the drive transistor DRT. Therefore, in the case where the reset operation is not executed, the potentials of the video signal lines DL must be greatly increased by the write operation during the m+1-th row selection period in order to display a gray level within a low gray level range on the pixels PX in the m+1-th row. That is, the potentials of the video signal lines DL must be greatly increased despite the small write currents I_{sig} For this reason, when the reset operation is not executed, it is difficult to precisely set each gate potential of the drive transistors DRT at a value corresponding to the magnitude of the write current I_{sig} by the write operation during the m+1-th row selection period.

In contrast, when the above reset operation is executed, the potentials of the video signal lines DL at the time just starting the write operation during the m-th row selection period are set at the reset potential Vᵣₛₜ. Since the reset potential Vᵣₛₜ is the sum of the potential V_{dd} and the mean value Vₜₕ2 (Av), the reset potential Vᵣₛₜ can be set almost equal to or lower than the sum V_{dd}+Vₜₕ1 by appropriately set the threshold voltage Vₜₕ2 of each reset transistor RST. Therefore, according to the driving method, it is possible to prevent each gray level within the low gray level range from being displayed higher than that to be displayed.

Further, according to the driving method, the magnitude of a current flowing from each pixel PX to the video signal line DL is small during the period from starting the reset operation until the potential of the video signal line DL reaches to the reset potential Vᵣₛₜ. However, according to the driving method, switches SWd of all the pixels PX connected to the same video signal line DL are closed during the reset period. That is, during the period from starting the reset operation until the potential of the video signal line DL reaches to the reset potential Vᵣₛₜ, currents flow from all the pixels PX connected to the same video signal line DL into the video signal line DL. Therefore, although the magnitude of the current flowing from each pixel PX to the video signal line DL is small, the potential of the video signal line DL can be set to the reset potential Vᵣₛₜ in a sufficiently short time after starting the reset operation.

In the present embodiment, the pixels PX employ the configuration shown in FIG. 3. The pixels PX may employ other configurations. For example, the diode-connecting switch SWc may be connected between the drain of the drive transistor DRT and the video signal line DL instead of connecting it between the drain and gate of the drive transistor DRT. Alternatively, the selector switch SWb may be connected to the gate of the drive transistor DRT and the video signal line DL instead of connecting it between the drain of the drive transistor DRT and the video signal line DL.

The reset transistor RST and reset switch SWd may be connected in series between the first power supply terminal as the second constant-potential terminal and the video signal line DL in this order. In this case, the gate of the reset transistor RST may be connected to the source of the reset switch SWd or the video signal line DL.

In the present embodiment, the control lines CL are arranged in almost parallel with the scan signal lines SL1 and SL2. The control lines CL may be arranged in almost parallel with the video signal lines DL. Further, the control lines CL may be connected to the video signal line driver XDR or another circuit instead of connecting it to the scan signal line driver YDR.

Additional advantages and modifications will readily occur to those skilled in the art. Therefore, the invention in its broader aspects is not limited to the specific details and representative embodiment shown and described herein. Accordingly, various modifications may be made without departing from the spirit or scope of the general inventive concept as defined by the appended claims and their equivalents.

What is claimed is:

1. A display comprising pixels and video signal lines arranged correspondently with columns which the pixels form, each of the pixels comprising:
a drive circuit including a drive transistor whose source is connected to a first power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor;
a reset circuit including a reset transistor and a reset switch connected in series between a second constant potential terminal and the video signal line, a drain of the reset transistor being directly connected to a gate of the reset transistor or connected to the gate of the reset transistor via the reset switch;
a display element including a pixel electrode, a counter electrode connected to a second power supply terminal, and an active layer interposed between the pixel electrode and the counter electrode; and
an output control switch connected between the drain of the drive transistor and the pixel electrode.

2. The display according to claim 1, further comprising a video signal line driver to which the video signal lines are connected, wherein the display is configured to disconnect the video signal lines from the video signal line driver in a reset period during which the reset switch is closed.

3. The display according to claim 2, wherein the display is configured to simultaneously execute a switching operation of the reset switch in all of the pixels.

4. The display according to claim 1, further comprising a video signal line driver to which the video signal lines are connected,
wherein the display is configured to sequentially select rows which the pixels form and execute a write operation on each of the pixels included in the selected row, the write operation including switching the connection state from the second state to the first state, making the video signal line driver output a video signal to the pixel via the video signal line, and switching the connection state from the first state to the second state while keeping the reset switch and the output control switch opened, and
wherein the display is configured to execute a reset operation every time before executing the write operation, the reset operation including disconnecting the video signal lines from the video signal line driver and closing the reset switch in each of the pixels while keeping the second state in each of the pixels.

5. The display according to claim 4, wherein the display is configured to execute the reset operation in a period during which the output control switch is closed in each of the pixels.

6. The display according to claim 1, wherein the first and second constant potential terminals are connected to the first power supply terminal.

7. The display according to claim 1, wherein the switch group includes a selector switch connected between the drain of the drive transistor and the video signal line, and a diode-connecting switch connected between the drain and gate of the drive transistor.

8. The display according to claim 1, wherein the display element is an organic EL element.

9. An array substrate comprising pixel circuits and video signal lines arranged correspondently with columns which the pixel circuits form, each of the pixel circuits comprising:
a drive circuit including a drive transistor whose source is connected to a power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor;
a reset circuit including a reset transistor and a reset switch connected in series between a second constant potential terminal and the video signal line, a drain of the reset transistor being directly connected to a gate of the reset transistor or connected to the gate of the reset transistor via the reset switch;
a pixel electrode; and
an output control switch connected between the drain of the drive transistor and the pixel electrode.

10. The array substrate according to claim 9, wherein the first and second constant potential terminals are connected to the power supply terminal.

11. The array substrate according to claim 9, wherein the switch group includes a selector switch connected between the drain of the drive transistor and the video signal line, and a diode-connecting switch connected between the drain and gate of the drive transistor.

12. A method of driving a display comprising pixels, video signal lines arranged correspondently with columns which the pixels form, and a video signal line driver to which the video signal lines are connected, each of the pixels comprising a drive circuit including a drive transistor whose source is connected to a first power supply terminal, a switch group which switches a connection state between a first state that drain and gate of the drive transistor and the video signal line are connected to one another and a second state that the drain and gate of the drive transistor and the video signal line are disconnected from one another, and a capacitor which is connected between a first constant potential terminal and the gate of the drive transistor, a reset circuit including a reset transistor and a reset switch connected in series between a second constant potential terminal and the video signal line, a drain of the reset transistor being directly connected to a gate of the reset transistor or connected to the gate of the reset transistor via the reset switch, a display element including a pixel electrode, a counter electrode connected to a second power supply terminal, and an active layer interposed between the pixel electrode and the counter electrode, and an output control switch connected between the drain of the drive transistor and the pixel electrode, comprising:
sequentially selecting rows which the pixels form;
executing a write operation on each of the pixels included in the selected row, the write operation including switching the connection state from the second state to the first state, making the video signal line driver output a video signal to the pixel via the video signal line, and switching the connection state from the first state to the second state while keeping the reset switch and the output control switch opened; and
executing a reset operation every time before executing the write operation, the reset operation including disconnecting the video signal lines from the video signal line driver and closing the reset switch in each of the pixels while keeping the second state in each of the pixels.

13. The method according to claim 12, wherein the reset operation is executed in a period during which the output control switch is closed in each of the pixels.
